(19) United States
(12) Patent Application Publication
(10) Pub. No.: US 2007/0295994 A1
(43) Pub. Date: Dec. 27, 2007

(54) HETERO JUNCTION BIPOLAR TRANSISTOR

(76) Inventors: Kazuhiro Mochizuki, Tokyo (JP); Hidetoshi Matsumoto, Kokubunji (JP); Shinichiro Takatani, Musashino (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/685,796

(22) Filed: Mar. 14, 2007

(30) Foreign Application Priority Data
Jun. 23, 2006 (JP) 2006-173730

(51) Int. Cl. H01L 29/739; H01L 27/082

(52) U.S. Cl. 257/197; 257/51; 257/198; 257/E29.188; 257/E27.053

(57) ABSTRACT

A hetero-junction bipolar transistor is provided including emitter contact region, an emitter region made of a first semiconductor material, a base region made of a second semiconductor material having a smaller energy band gap than the first semiconductor material, a collector region made of the first semiconductor material, and a collector contact area, the regions being serially formed on a surface of a substrate in a direction parallel to the surface thereof. A buffer layer made of a third semiconductor material with an energy band gap larger than the first semiconductor material is provided between the emitter region, the base region, the collector region and the substrate surface. Emitter, base and collector electrodes are also provided, in contact with the emitter contact region, the base region, and the collector region, respectively.

### CLAIM OF PRIORITY

The present application claims priority from Japanese Application JP 2006-173730 filed on Jun. 23, 2006, the content of which is hereby incorporated by reference into this application.

### BACKGROUND OF THE INVENTION

1. Technical field

The present invention relates to a lateral bipolar transistor. More specifically, the invention relates to a lateral power bipolar transistor which has a high base-collector breakdown voltage, a high current gain, and a low base resistance.

2. Related Art

It is known that Japanese Patent No. 3715477 discloses a lateral bipolar transistor having a structure in which GaN and AlGaN are used as semiconductor materials. FIG. 2 is a cross sectional view of an example of the structure schematically illustrating a vertical cross-sectional view of the structure. In FIG. 2, an emitter region 24 made of n-type GaN and a collector region 23 made of n-type GaN are disposed above a substrate 21 via a first base layer 51 made of p-type GaN, a second base layer 52 made of p-type AlGaN, and a third base layer 53 made of P-type GaN. An emitter electrode 29, a base electrode 30, and a collector electrode 31 are disposed in contact with the emitter region 24, the first base layer 51, and the collector region 23, respectively. In this structure, the second base layer has a relatively larger forbidden band gap than those in the first and third base layers, and therefore electrons injected from the emitter region 24 into the third base layer 53 can reach the collector region 23 without leaking to the substrate 21, which contributes to improvement in current gain.

In a mesa-type npn bipolar transistor, there is a trade off between lateral diffusion and recombination of electrons injected from an emitter layer into a base layer and a distance from a high density base contact region to an emitter mesa, and therefore improvement in current gain and size reduction of the transistor can not be achieved concurrently. The problems are described in detail below with reference to the conventional technique.

In the conventional technique as described above, a base-collector withstand voltage is determined not by a thickness W in the lateral direction of the collector region 23, but by a thickness d in the depth direction. When the substrate 21 made of GaN is used, the thickness d can be made sufficiently large. However, since that a diameter of a GaN substrate currently available is at most 2 inches and that the substrate is extremely expensive, such a material as Si or SiC is used as a material for the substrate 21. When such a material as Si or SiC is used, a stress is generated in a GaN epitaxial growth film due to a difference between a thermal expansion coefficient of the GaN epitaxial growth film and that of the substrate, and when the thickness d is over 2 μm, cracks are generated. For the reason described above, even if the thickness W is made larger in the state where cracks are not generated, a base-collector breakdown voltage is not increased, which is a first problem.

In the conventional technique, since a homo junction is used for junction between an emitter and a base, the current gain is rather low, which is a second problem.

Furthermore, in the conventional technique, since an acceptor level in the p-type GaN base is deep and also a solid solubility level is low, the base resistance can hardly be lowered, which is a third problem.

The present invention was made to solve the three problems described above. An object of the present invention is to provide a hetero-junction power bipolar transistor ensuring a sufficient base-collector breakdown voltage and a high current gain and also enabling reduction of a base resistance. The hetero-junction bipolar transistor according to the present invention is suitable for the lateral hetero-junction bipolar transistor, and can advantageously be used as a power bipolar transistor.

In a first aspect of the present invention, an emitter contact region, an emitter region made of a first semiconductor material (energy band gap: Eg2), a base region made of a second semiconductor material (energy band gap: Eg1) with the energy band gap smaller than that of the first semiconductor material, a collector region made of the first semiconductor material, and a collector contact region are successively formed in a direction parallel to a substrate, and a buffer layer made of a third semiconductor material (energy band gap: Eg3) with the energy band gap larger than that of the first semiconductor material is provided between each of the emitter region, the base region, and the collector region and a surface of the substrate. Furthermore, an emitter electrode, a base electrode, and a collector electrode are disposed in contact with the emitter contact region, the base region, and the collector region, respectively. The relation among the energy band gaps is Eg2<Eg1<Eg3. Thus, the first problem can basically be solved by using this structure.

In a second aspect of the present invention, the emitter region and the collector region are made of n-type InGaN, the base region is made of p-type polycrystalline Si, and the buffer layer is made of AlGaN. The second problem can be solved by the structure described above.

In a third aspect of the present invention, an acceptor density in the base region is higher than a donor density in the emitter region. The third problem described above can be solved by the structure.

When a typical donor density in the emitter region is, for instance, 1×10¹⁷ cm⁻³, an acceptor density in a base region is about 1×10¹⁶ cm⁻³ in the conventional technology, but in the present invention, even when the acceptor density is substantially increased up to around 2×10¹⁹ cm⁻³, a current gain not causing any problem in actual use can be achieved.

With the present invention, by combining the structures in the first to third aspects according to the necessity, each of the effects described above can be realized.

Furthermore, according to the third aspect of the present invention, it is possible to provide a semiconductor device enabling reduction of a contact resistance in a conductive layer of a semiconductor alloy made of GaN or mainly made of GaN. Namely, it is possible to provide a semiconductor device in which a polycrystalline Si layer is present between a semiconductor alloy layer made of GaN or mainly made of GaN and an ohmic electrode. The third aspect of the present invention is described in detail in “Detailed Description of Preferred Embodiments” section below.

The structure according to the first aspect of the present invention provides the effect that a base-collector breakdown voltage sufficient for practical use can be realized. The structure according to the second aspect of the present invention provides the effect that a current gain can be improved. Furthermore, the structure according to the third aspect of the present invention provides the effect that a base resistance can be reduced.

Therefore, in the present invention, by combining the three structures according to the necessity, it is possible to provide a hetero-junction bipolar transistor ensuring a base-collector breakdown voltage and a current gain sufficient for practical use and also suitable for reduction of a base resistance. Furthermore, the present invention can advantageously be applied to a lateral power bipolar transistor.

### BRIEF DESCRIPTION OF THE DRAWINGS

FIG. 1 is a vertical cross-section of a structure according to a first embodiment of the present invention;

FIG. 2 is a vertical cross-sectional view of a conventional lateral bipolar transistor;

FIG. 3 is a vertical cross-section of a structure including regions successively formed in a manufacturing process according to a first embodiment of the present invention;

FIG. 4 is a vertical cross-section of a structure including regions successively formed in the manufacturing process according to the first embodiment of the present invention;

FIG. 5 is a vertical cross-section of a structure including regions successively formed in the manufacturing process according to the first embodiment of the present invention;

FIG. 6 is a vertical cross-section of a structure including regions successively formed in the manufacturing process according to the first embodiment of the present invention;

FIG. 7 is a vertical cross-section of a structure including regions successively formed in the manufacturing process according to the first embodiment of the present invention;

FIG. 8 is a vertical cross-section of a structure including regions successively formed in the manufacturing process according to the first embodiment of the present invention;

FIG. 9 is a plan view illustrating the first embodiment of the present invention;

FIG. 10 is a schematic illustrating a band structure taken along the line A-A′ of FIG. 9;

FIG. 11 is a plan view illustrating a second embodiment of the present invention;

FIG. 12 is a view illustrating a dependency of a current gain on an InN mole fraction in the first embodiment of the present invention;

FIG. 13 is a vertical cross sectional view of a conventional light-emitting diode;

FIG. 14 is a vertical cross sectional view illustrating a third embodiment of the present invention;

FIG. 15 is a plan view illustrating a conventional light-emitting diode;

FIG. 16 is a plan view illustrating the third embodiment of the present invention;

FIG. 17 is a vertical cross sectional view of a structure including regions successively formed in a manufacturing process according to a fourth embodiment of the present invention;

FIG. 18 is a vertical cross sectional view of a structure including regions successively formed in the manufacturing process according to the fourth embodiment of the present invention;

FIG. 19 is a vertical cross sectional view of a structure including regions successively formed in the manufacturing process according to the fourth embodiment of the present invention;

FIG. 20 is a vertical cross sectional view of a structure including regions successively formed in the manufacturing process according to the fourth embodiment of the present invention;

FIG. 21 is a vertical cross sectional view of a structure including regions successively formed in the manufacturing process according to the fourth embodiment of the present invention;

FIG. 22 is a vertical cross sectional view of a structure including regions successively formed in the manufacturing process according to the fourth embodiment of the present invention;

FIG. 23 is a vertical cross sectional view of a structure including regions successively formed in the manufacturing process according to the fourth embodiment of the present invention;

FIG. 24 is a vertical cross sectional view of a structure including regions successively formed in the manufacturing process according to the fourth embodiment of the present invention;

FIG. 25 is a vertical cross sectional view of a structure including regions successively formed in the manufacturing process according to the fourth embodiment of the present invention;

FIG. 26 is a vertical cross-sectional view of a structure including regions successively formed in the manufacturing process according to the fourth embodiment of the present invention; and

FIG. 27 is a vertical cross-section according to the fourth embodiment of the present invention.

### DETAILED DESCRIPTION OF THE PREFERRED EMBODIMENTS

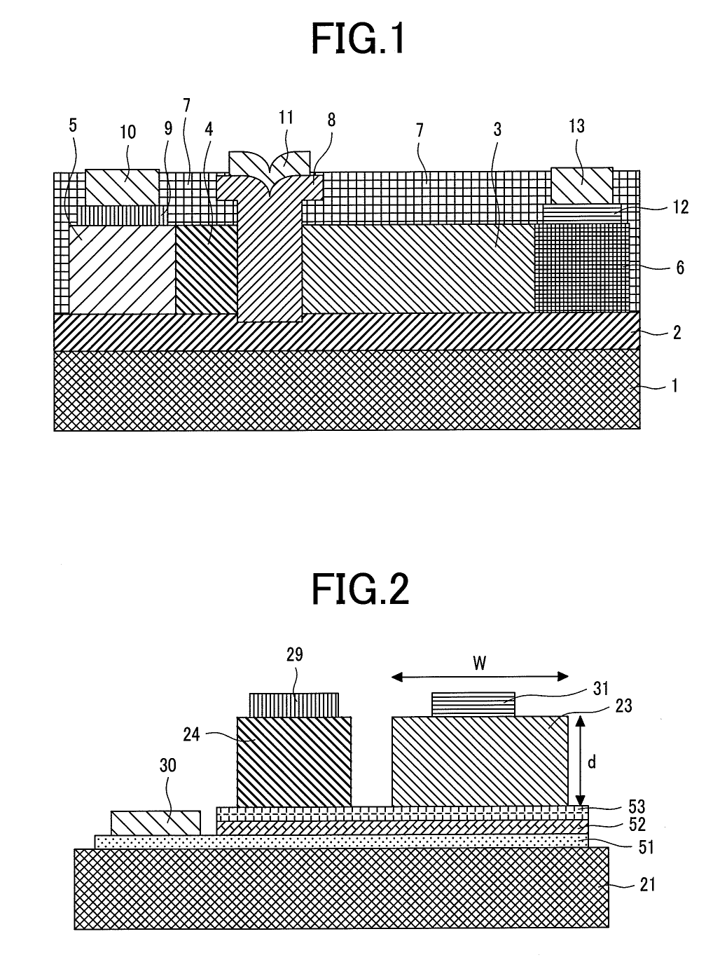

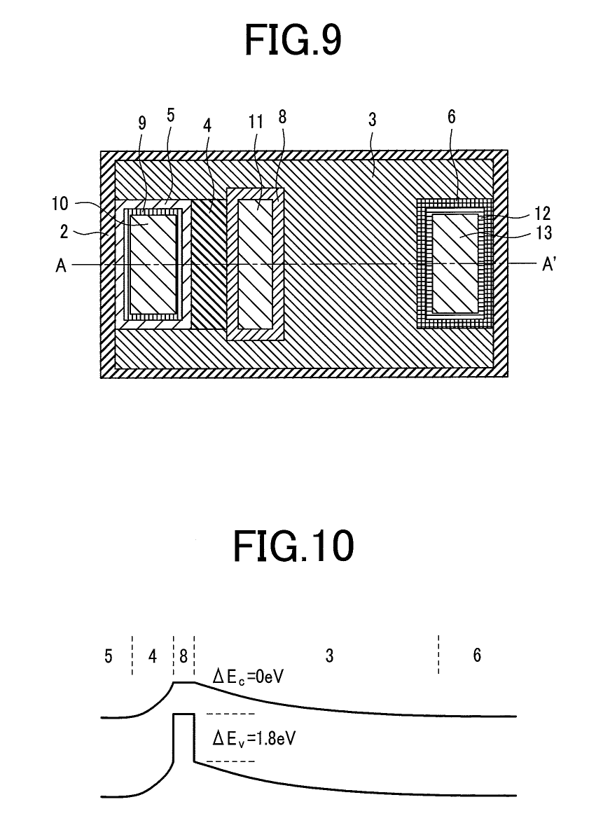

Prior to description of specific embodiments of the present invention, effects of the present invention are described with reference to FIG. 1, FIG. 9, and FIG. 10. FIG. 1 is a vertical cross-sectional view of a representative lateral bipolar transistor; FIG. 9 is a plan view illustrating the bipolar transistor; and FIG. 10 is a view schematically illustrating a band structure taken along the line A-A′ of FIG. 10.

FIG. 1 is a vertical cross-sectional view of a structure of a bipolar transistor. In FIG. 1, an emitter contact region 5 made of high-doping n-type InGaN, an emitter region 4 made of n-type InGaN, base region 8 made of polycrystalline Si, a collector region 3 made of n-type InGaN, and a collector contact region 6 made of high-doping n-type InGaN are disposed above a substrate 1 via a buffer layer 2 made of undoped AlGaN according to the order described above in a direction parallel to a surface of the substrate 1. Furthermore, an emitter electrode 9, a base electrode 8, and a collector electrode 12 are disposed in contact with the emitter contact region 5, the base region 8, and the collector contact region 6, respectively. Wirings 10, 11, and 13 made of Al or Au are provided on the electrodes by forming contact holes on a SiON film 7 used as a surface passivation film. FIG. 9 is a plan view illustrating the lateral bipolar transistor shown in FIG. 1, and illustrates the bipolar transistor in the state where the surface passivation film 7 has been removed from the state shown in FIG. 1 in order to clarify the configuration for each of the regions. The same reference numerals as those used in FIG. 1 are assigned to the corresponding components in FIG. 9.

The buffer layer 2 made of undoped AlGaN substantially functions as an insulator when the AlN mole fraction is over 0.2. Differently from the conventional structure, a conductive layer is not present between the collector region 3 and the substrate 1. Because of the structure, the base-collector breakdown voltage is not limited by a thickness in the depth direction of the collector region 3, and the base-collector breakdown voltage can be improved by making larger a distance between the base electrode 8 and the collector electrode 12.

FIG. 10 is a schematic illustrating a band structure of a semiconductor region taken along the line A-A′ of FIG. 9. Namely, the emitter contact region 5, the emitter region 4, the base electrode 8, the collector region 3, and the collector contact region 6 are disposed in successive contact. An upper curve in the figure shows a lower edge of the conductive band, while a lower curve in the figure shows an upper edge of a valence band.

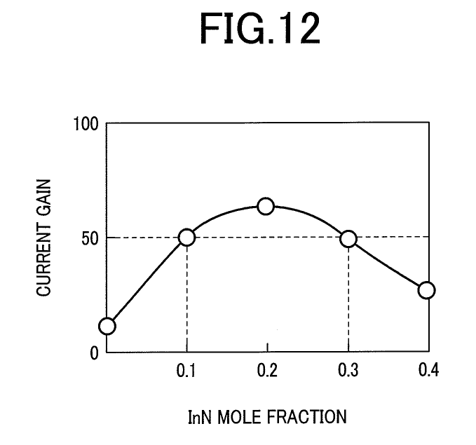

By forming the emitter region 4 and the collector contact region 6 with In_{0.2}Ga_{0.8}N, a conduction-band discontinuity ΔEc in the emitter-base junction and in the base-collector junction is substantially reduced to zero, and also a valence-band discontinuity ΔEv can be set to about 1.8 eV, which is an extremely larger as compared to the thermal energy kT (26 meV at a room temperature, wherein K denotes a Boltzmann constant and T denotes an absolute temperature). Therefore, a reverse injection of holes from the base region to the emitter region can be reduced to a substantially ignorable level as compared to that in a conventional homo-junction bipolar transistor. Therefore, the current gain can advantageously be made higher than 50 as required in the actual use. It is to be noted that, although the same effect can be provided when the InN mole fraction in InGaN used for the emitter region and the collector region is 0.1 or more, when the mole fraction is over 0,3, a dislocation density increases due to the lattice mismatch leading to increase of a recombination current. As a result, the current gain drops to 50 or below, and therefore the InN mole fraction is desirably in the range from 0.1 to 0.3. An example of change in a current gain dependent on the InN mole fraction is shown in FIG. 12. The desirable range described above can fully be understood from this figure. As understood from the figure, the InN mole fraction is preferably in the range from 0.1 to 0.3. From a view point of reduction of power consumption, it is necessary to reduce a base current to an ignorable level against a collector current, and in a case of a hetero bipolar transistor (HBT), the current gain is generally set to 100 or more, and at least to 50 or more in actual use.

Furthermore, by employing the large valence band discontinuity ΔEv as described above, it is possible to make an acceptor density in the base region larger as compared to a donor density in the emitter region. For instance, even when B (boron) is used as an acceptor in the base region 8 and the density is set to, for instance, about 3×10¹⁹ cm⁻³ which is about 100 times higher than the typical donor density of 3×10¹⁷ cm⁻³ in the emitter region 4, degradation of the current gain can be reduced to an extremely low level. Because of the feature, reduction of a base resistance, which is difficult in a conventional p-type GaN base, can easily and advantageously be realized.

Next, a lateral hetero-junction bipolar transistor and a process for manufacturing the bipolar transistor are described below with reference to the related drawings.

### First Embodiment

As a first embodiment of the present invention, an example of an npn-type hetero-junction bipolar transistor having the structure of InGaN/polycrystalline Si/InGaN is described. The device and a process for producing the device are described with reference to FIG. 1 and FIGS. 3 to 9. The transistor is referred to as “npn-type InGaN/polycrystalline Si/InGa hetero-junction bipolar transistor” in the following description.

FIG. 1 is a vertical cross-section of a structure of an npn-type InGaN/polycrystalline Si/InGa hetero-junction bipolar transistor according to a first embodiment of the present invention, and FIG. 9 is a plan view illustrating the npn-type InGaN/polycrystalline Si/InGa hetero-junction bipolar transistor. The emitter contact region 5 made of highly doped n-type In_{0.2}Ga_{0.8}N, the emitter region 4 made of n-type In_{0.2}Ga_{0.8}N, the base electrode 8 made of polycrystalline Si, the collector region 3 made of n-type In_{0.2}Ga_{0.8}N, and the collector contact region 6 with highly doped n-type In_{0.2}Ga_{0.8}N are successively disposed above a high resistance Si substrate (with the resistivity larger than 1 KΩ cm, (111) surface) via the buffer layer 2 made of undoped Al_{0.2}Ga_{0.8}N in a direction parallel to a surface of the substrate 1. The emitter electrode 9, the base electrode 8, and the collector electrode 12 are disposed in contact with the emitter contact region 5, the base region 8, and the collector contact region 6, respectively. Al wirings 10, 11, 13 are provided by forming contact holes on the SiON films each functioning as a surface passivation film on the electrodes. FIG. 9 is a plan view illustrating the bipolar transistor shown in FIG. 9, and the surface passivation film 7 shown in FIG. 1 is removed so that structures of each region can be visually confirmed.

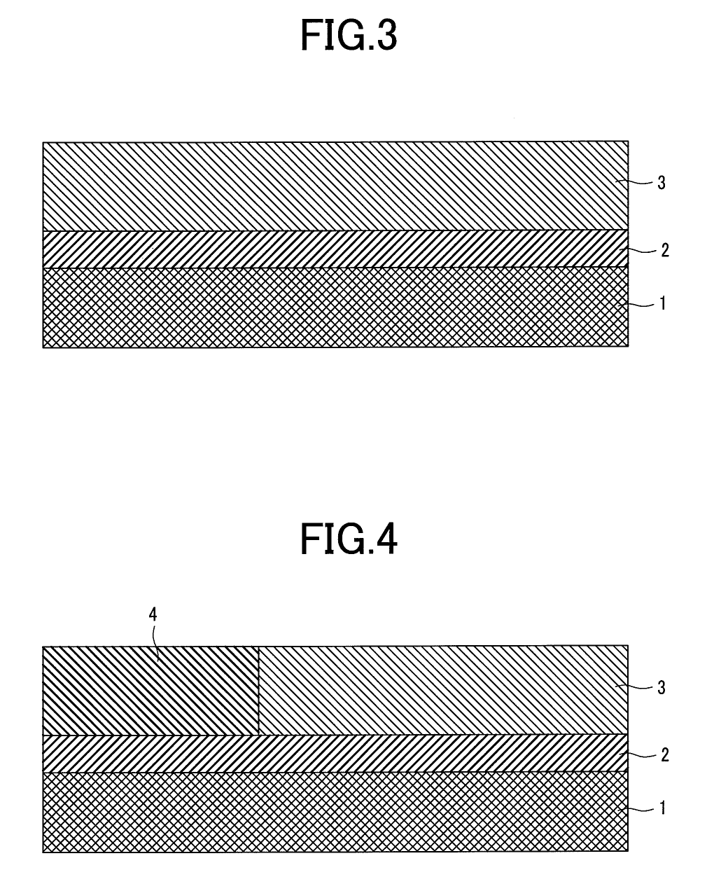

A method of manufacturing the transistor according to the present invention is described below with reference to FIG. 3 to FIG. 8. FIG. 3 to FIG. 8 are cross-sectional views each illustrating the device including regions successively formed in the manufacturing process. At first, the buffer layer 2 made of undoped Al_{0.2}Ga_{0.8}N (with the thickness of 0.5 μm) and the layer 3 made of n-type In_{0.2}Ga_{0.8}N (with the Si density of 2×10¹⁶ cm⁻³ and the thickness of 1.5 μm) are epitaxially grown above the high resistance Si substrate 1 (with the resistivity smaller than 1 KΩ, (111) surface) by using a general-purpose metal organic chemical vapor deposition apparatus (Refer to FIG. 3).

Then, Si is ion-implanted to the emitter region 4 using a SiON film or a film of metal such as Ni as a mask (Refer to FIG. 4). In this step, an ion dose is set so that a donor density in the emitter region 4 is equal to or more than 1.0×10¹⁷ cm^{31 3} and less than 1.0×10¹⁸ cm^{31 3} (Note that the ion dose is set so that the final donor density is 3×10¹⁷ cm^{31 3} to provide an activation ratio of 50% after annealing in this embodiment). Although Si is implanted also to a portion of the buffer layer 2 made of updoped AlGaN with the Al/Ga mole fraction of 0.2/0.8, Si in the buffer layer 2 made of updoped Al_{0.2}Ga_{0.8}N is little activated, and the effect is ignorable.

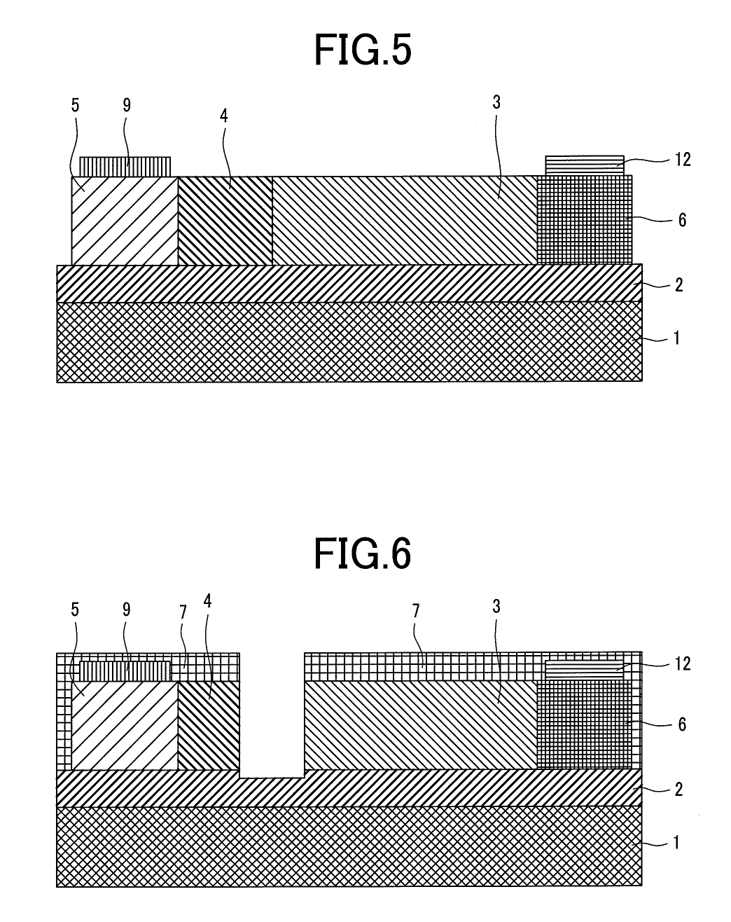

Then, Si is ion-implanted to regions to be processed to the emitter contact region 5 and to the collector contact region 6 using the same mask as that used for formation of the emitter region. In this step, the ion dose is determined so that the donor densities in the emitter contact region 5 and the collector contact region 6 are equal to or more than 1.0×10¹⁹ cm^{31 3} and less than 1.0×10²⁰ cm⁻³. Although Si is implanted also to a portion of the buffer layer 2 made of undoped Al_{0.2}Ga_{0.8}N, Si in the buffer layer 2 made of undoped Al_{0.2}Ga_{0.8}N is little activated, and the effect is ignorable. Then the Si implanted to the emitter region 4, the emitter contact region 5 and the collector contact region 6 is annealed for activation. Furthermore, an n-type electrode made of Ti, Ni, or the like is formed on the emitter contact region 5 as well as on the collector contact region 6 by the lift-off method (Refer to FIG. 5).

Then the SION film 7 is deposited above the entire surface, and the emitter region 4 and the collector region 3 for forming a base are removed by means of photolithography and dry etching. In this step, even when etching is performed under the condition that the In_{0.2}Ga_{0.8}N is larger in etching rate than Al_{0.2}Ga_{0.8}N, it is difficult to lower the selectivity to zero. Thus, the buffer layer 2 made of undoped Al_{0.2}Ga_{0.8}N is over-etched. However, when the over-etched depth is not more than a thickness of the buffer layer 2 (namely 0.5 μm in this embodiment), no problem occurs (Refer to FIG. 6).

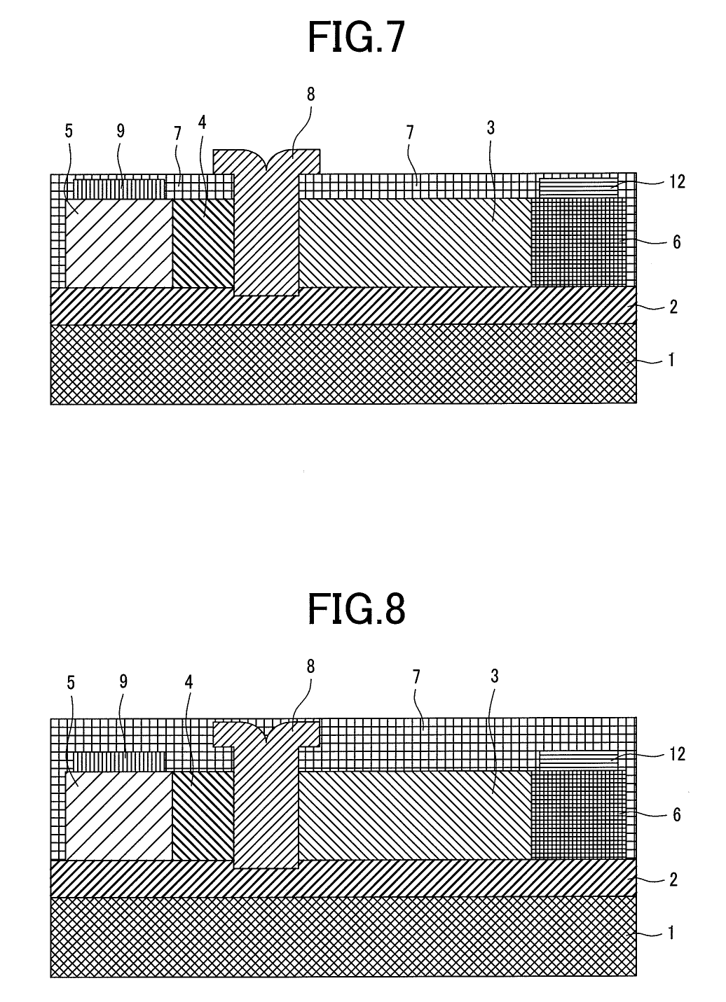

Then, by means of the chemical vapor deposition, B-doped polycrystalline Si (with the activated B density of 3×10¹⁹ cm⁻³) are implanted to the entire surface. Then the polycrystalline Si is left only in the base region 8 by photolithography and dry etching (Refer to FIG. 7).

Then, the SiON film 7 is again deposited (Refer to FIG. 8), polycrystalline Si is ion-implanted to the emitter electrode 9 and to the base region 8, an opening is provided on the collector electrode 12 by means of photolithography and dry etching, and Al is deposited on the entire surface. Finally, the Al-deposited surface is subjected to patterning by means of photolithography and dry etching to form the emitter wiring 10, the base wiring 10, and the collector wiring 13, thus a lateral hetero-junction bipolar transistor being completed.

In this embodiment, the buffer layer 2 made of undoped Al_{0.2}Ga_{0.8}N is an insulating body. Differently from the conventional technique, a conductive layer is not provided between the collector region 3 and the substrate 1, so that the base-collector breakdown voltage is not limited by a thickness (1.5 μm in this embodiment) in the depth direction of the collector region 3, and the base-collector withstand voltage can be set to 1 kV by widening the distance between the base region 8 and the collector contact region 12, for instance, to 15 μm.

Furthermore, in the embodiment, it is possible to realize an ideal double hetero-junction structure in which a conduction-band discontinuity ΔEc in the emitter-base junction and in the base-collector junction is substantially zero and a valence-band discontinuity ΔEv is about 1.8 eV, and therefore reverse injection of holes from the base region to the emitter region can be reduced to an ignorable level as compared to that in a conventional homo-junction bipolar transistor, so that the current gain can advantageously be improved.

In contrast to a low hole density of 1.0×10¹⁷ cm^{31 3} or less at a room temperature in a conventional p-type GaN layer, in the embodiment described above, it is possible to realize an extremely high density of holes of 3×10¹⁹ cm⁻³ with polycrystalline Si. Because of the feature, reduction of a base resistance, which has been difficult in the conventional p-type GaN base, can advantageously and easily be realized.

### Second Embodiment

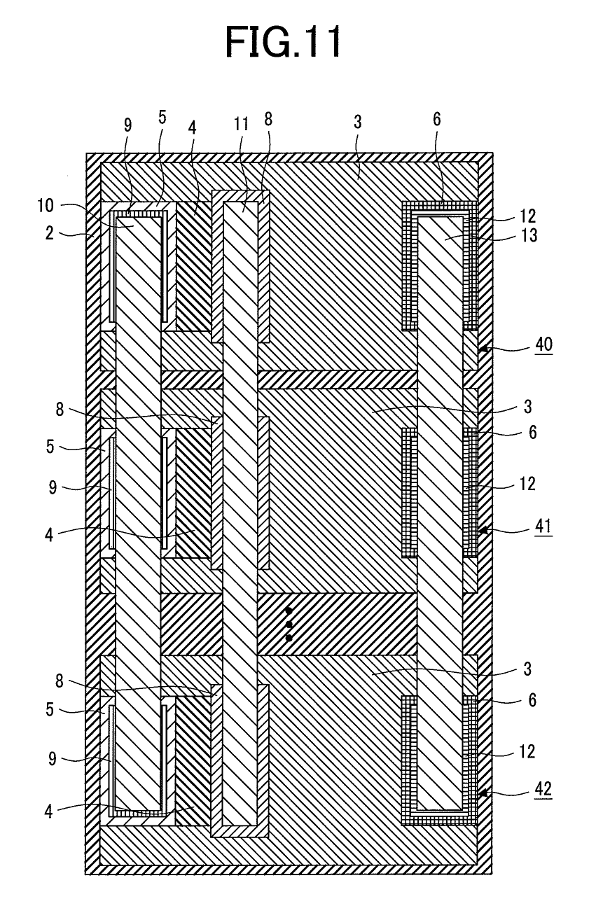

In a second embodiment of the present invention, a plurality of lateral hetero-junction bipolar transistors are formed on a substrate. A plurality of lateral hetero-junction bipolar transistors described in the first embodiment above are provided with the buffer layer 2 made of undoped Al_{0.2}Ga_{0.8}N in common on a chip as shown in FIG. 11, and furthermore the emitter wirings 10, the base wirings 11, and the collector wirings 13 of the bipolar transistors are connected to each other respectively to form a multi-finger lateral hetero-junction bipolar transistor.

With the second embodiment of the present invention, it is possible to realize a base-collector breakdown voltage and a current gain sufficient for practical use, and also to realize a lateral high power bipolar transistor with a reduced base resistance.

### Third Embodiment

A third embodiment of the present invention provides a semiconductor having a structure in which a polycrystalline Si layer is provided between a semiconductor alloy layer made of GaN or containing GaN as a main ingredient and an ohmic electrode.

In the third embodiment, a relation between a width of the semiconductor alloy layer (Eg4) and that of the polycrystalline Si layer (Eg5) is Eg>Eg5. Furthermore it is required to employ a semiconductor made of a compound of elements belonging to III to V groups which is not decomposed at the temperature for formation of the polycrystalline Si film (in the range from 600° C. to 800° C.) and also which has a low vapor pressure of V group element. Namely, as an element belonging to the V group, P, As, and Sb are not allowable, and N should be employed. There are AlN, GaN, and InN as materials for substrates based on a compound of elements belonging to III to V groups in which N is employed as an element belonging to V group, but in a case of AlGaN with the AlN mole fraction of over 0.5, the material functions like an insulator, and in that case, doping control required for a semiconductor is difficult. On the other hand, in a case of InGaN with the InN mole fraction of over 0.5, In tends to be re-evaporated from the surface at the temperature required for formation of a polycrystalline Si film, which disadvantageously causes surface roughening. For the reasons as described above, materials made of GaN or containing GaN as a main ingredient (represented by AlₓGa_{y}In_{(1-x-y)}N) are optimal III-V compound semiconductors in combination with polycrystalline Si. In the AlₓGa_{y}In_{(1-x-y)}N, preferably the following conditions should be satisfied: 0≦x<0.5 and 0≦y≦1.

In the embodiment, the semiconductor alloy layer, the polycrystalline Si layer, and the conductor layer are laminated in the vertical direction, but the layers are arrayed in the horizontal direction.

A semiconductor alloy is a base material, and the polycrystalline Si layer should homogeneously cover the base material for reduction of a contact resistance, and therefore a thickness of the polycrystalline Si layer should be 10 nm or more.

In this embodiment, a height of a Schottky barrier between an n-type semiconductor containing GaN or GaN as a main ingredient and a metal is around 0.7 eV, which is large. In contrast, a contact resistance between polycrystalline Si and a metal can be reduced to an ignorable level by doping polycrystalline Si at a high density of 1×10¹⁹ cm^{31 3}. In addition, since conduction-band discontinuity between the n-type semiconductor made of GaN or containing GaN as a main ingredient and the polycrystalline Si is small, namely around 0.3 eV, the contact resistance between the n-type semiconductor made of GaN or containing GaN as a main ingredient and the metal can be made smaller by inserting the polycrystalline Si on the interface.

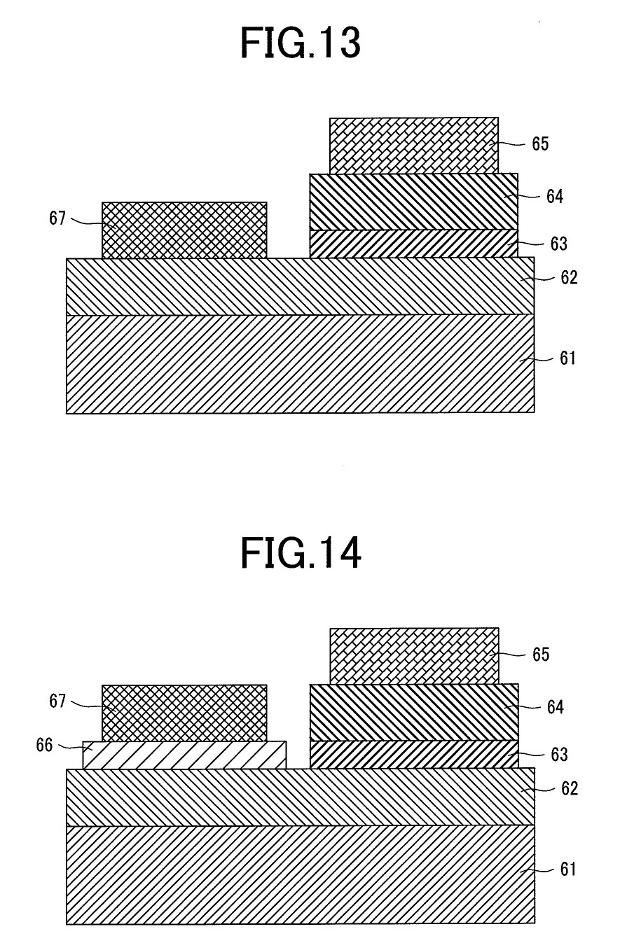

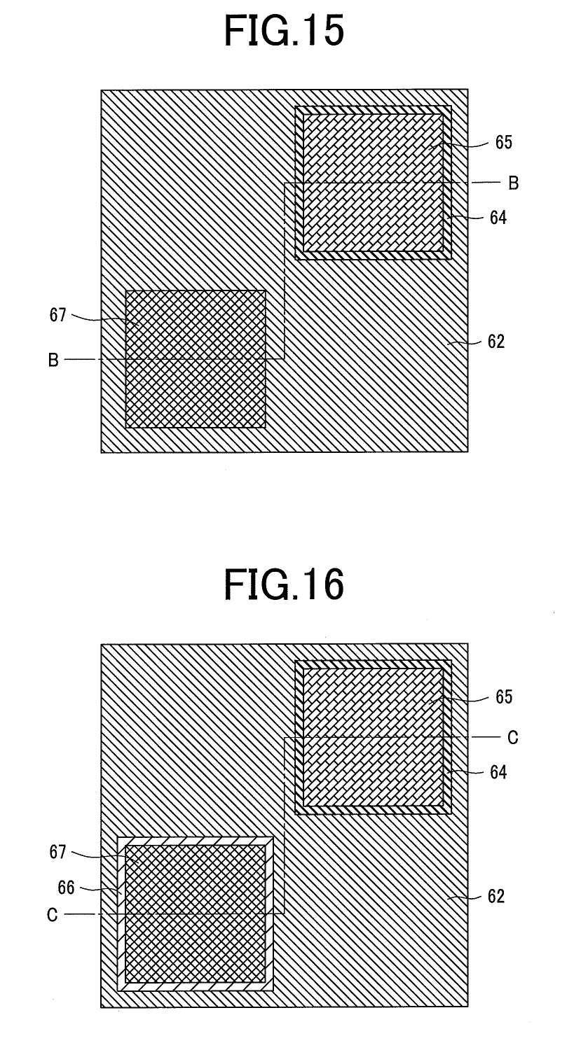

A specific example of the present invention is an application to a light emitting diode. More specifically, the application of polycrystalline Si to a semiconductor made of a GaN-based compound is further applied to a light emitting diode made of In_{0.2}Ga_{0.8}N. This example is described below with reference to FIG. 13 to FIG. 16. FIG. 13 and FIG. 15 each illustrate a conventional light emitting diode made of In_{0.2}Ga_{0.8}N. FIG. 13 is a cross-sectional view of the light emitting diode, while FIG. 15 is a plan view of the same. FIG. 14 and FIG. 16 illustrate a light emitting diode made of In_{0.2}Ga_{0.8}N according to this embodiment. FIG. 14 is a cross-sectional view of the light emitting diode, while FIG. 16 is a plan view of the same.

The conventional light emitting diode made of In_{0.2}Ga_{0.8}N as shown in FIG. 13 and FIG. 15 has a structure as described below. A double hetero structure including an n-type GaN layer 62 (with the thickness of 2 μm and Si concentration of 1×10¹⁸ cm^{31 3}), an active layer 63 made of undoped In_{0.2}Ga_{0.8}N (with the thickness of 1 μm), and a p-type GaN layer 64 (with the thickness of 2 μm and the Mg concentration of 1×10¹⁸ cm⁻³ is grown on a sapphire substrate 61 by metal organic chemical vapor deposition. Then, after a p-type electrode 65 (Ti/Al) is formed, a surface of the n-type GaN layer 62 is exposed by means of photolithography and etching. An n-type electrode 67 (Ti/Ni) is formed on the exposed surface of the n-type GaN layer 62. However, because a contact resistance between the n-type electrode 67 and the n-type GaN layer 62 is high, the quantum efficiency disadvantageously drops due to self heating of the element caused by a large ohmic loss.

In contrast, the light emitting diode made of In_{0.2}Ga_{0.8}N according to the present invention as shown in FIGS. 14 and 16 has a structure as described below. Namely, differently from the conventional structure as described above, a polycrystalline Si layer 66 (with the thickness of 0.1 μm and the P concentration of 1×10²⁰ cm⁻³) is inserted between the n-type electrode 67 and the n-type GaN layer 62. As a result, a contact resistance between the n-type electrode 67 and the n-type GaN layer 62 can be reduced. Other portions of the configuration are identical to those in the example of conventional technique described above.

With the embodiment described above, a temperature rise during operations of the light emitting diode made of In_{0.2}Ga_{0.8}N can be suppressed, which advantageously makes it possible to maintain the quantum efficiency at a high level. The light emitting diode according to the third embodiment of the present invention is described above, but it is needless to say that the present invention can be applied to any GaN-based optical device such as a semiconductor laser or to any GaN-based electronic device such as a junction type field-effect transistor in the same way.

### Fourth Embodiment

A fourth embodiment of the present invention is, like in the third embodiment of the present invention, an example of a semiconductor device in which a polycrystalline Si layer is present between a semiconductor alloy layer made of GaN or containing GaN as a main ingredient and an ohmic electrode.

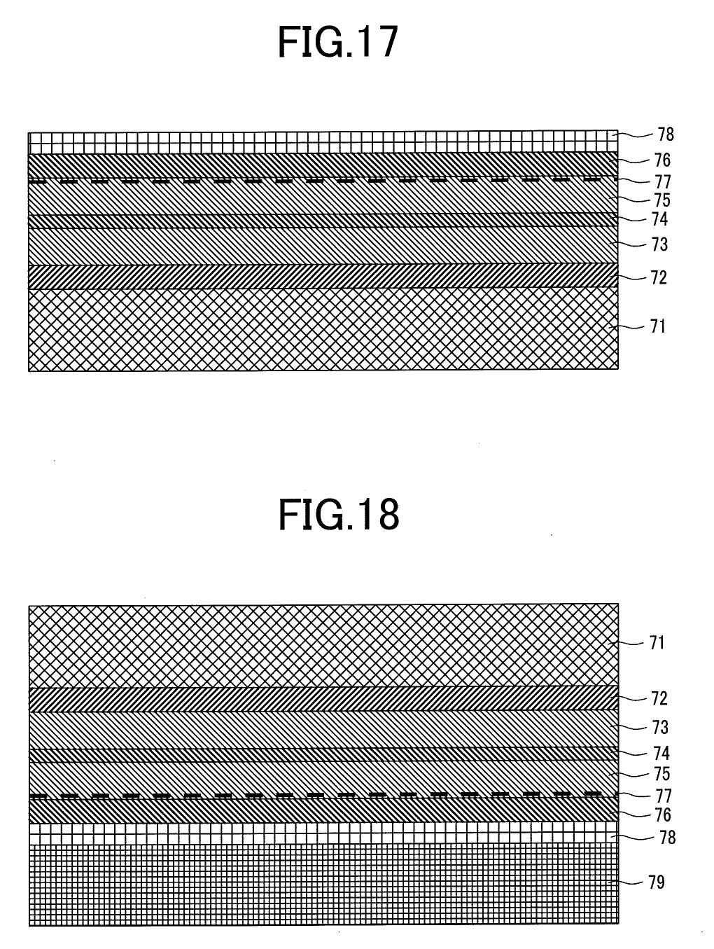

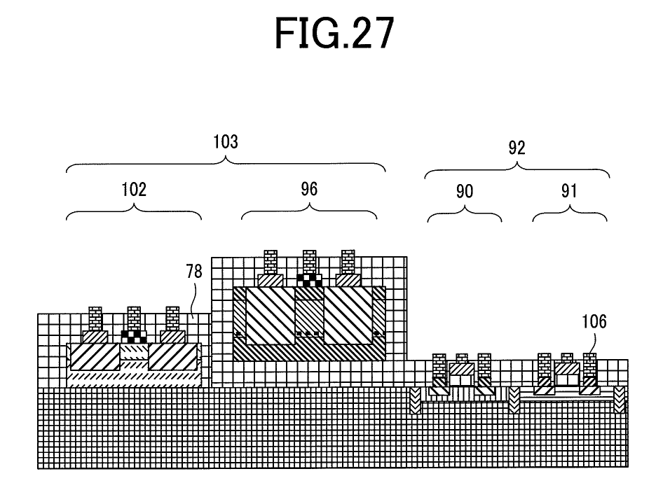

A specific example is an application of the present invention to an ultrahigh-speed LSI (large Scale Integrated Circuits). That is, in the example, the polycrystalline Si applied to the GaN-based compound semiconductor used in the first embodiment is applied to a field-effect transistor (FET) containing GaN in the n-type channel. This example is described with reference to FIG. 17 to FIG. 27. FIG. 27 is a cross-sectional view illustrating an ultrahigh-speed LSI including both an ultrahigh-speed complementary FET 103 and the conventional type of Si CMOSFET 92 formed on a Si (100) substrate 79 on the same chip, the ultrahigh-speed complementary FET 103 including an ultrahigh-speed n-channel GaN FET 96 and an ultrahigh-speed p-channel Ge FET 102. Furthermore, FIGS. 17 to 26 are cross-sectional views illustrating a structure including regions successively formed according to a manufacturing process shown in FIG. 27.

At first, a buffer layer 72 made of undoped AlGaN (with AiN and AlGa alloy laminated and also with the thickness of 0.2 μm), a buffer layer 73 made of undoped GaN buffer (with the thickness of 0.3 μm), an etch-stop layer 74 made of undoped AlGaN (with the AlN mole fraction of 0.05 and with the thickness of 0.1 μm), a layer 75 made of undoped GaN (with the thickness of 1 μm), and a layer 76 made of undoped AlGaN (wi the AlN mole fraction of 0.25 and with the thickness of 3 μm) are grown by metal organic chemical vapor deposition on the Si (111) substrate 71. A Si (111) surface is used for the substrate 71, and therefore both GaN and AlGaN are hexagonal. In addition, on an interface between the layer 75 made of undoped GaN and the layer 76 made of undoped AlGaN, a two-dimensional electron gas (sheet electron concentration of 1×10¹³ cm⁻² and electron mobility of 2000 cm²/Vs) are formed in association with spontaneous polarization and piezo polarization. Then, an SiO₂ film 78 (with the thickness of 0.5 μm) is deposited by means of chemical vapor deposition (Refer to FIG. 17).

Next, the SiO₂ of the sample is placed in contact with a surface of the Si (100) substrate 79, and the surfaces are fused to each other by applying a load at the temperature of 1000° C. (Refer to FIG. 18).

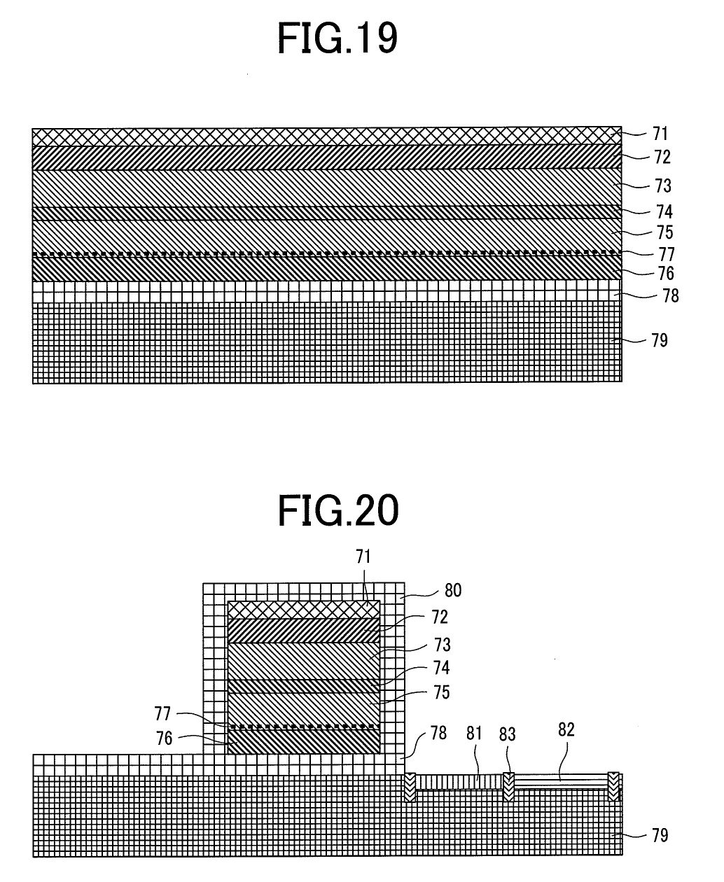

Then the Si (100) substrate 79 is adhered to a glass substrate, and the Si (iii) substrate 71 is thinned from the rear surface down to the thickness of 50 μm with a polishing machine (Refer to FIG. 19).

Then, the Si (111) substrate 71 other than in the region for formation of the n-channel GaN FET 96, the buffer layer 72 made of undoped AlGaN, the buffer layer 73 made of undoped GaN buffer, the etch-stop layer 74 made of undoped AlGaN, a layer 75 made of undoped GaN (with the thickness of 1 μm), and the layer 76 are removed by photolithography and dry etching. Then, by chemical vapor deposition, a SiO₂ film 80 (with the thickness of 0.5 μm) is formed substantially isotropically, and the SiO₂ film 80 in a region for formation of the Si CMOSFET 92 is removed by photolithography and dry etching. Then, a p-type Si well 81 and an n-type Si well 82 are formed by photolithography, ion-implanting, and annealing for activation. In addition, a trench for device isolation is formed by photolithography and dry etching, and a region for device isolation 83 by deposition of SiO₂ film and etching back the film (Refer to FIG. 20).

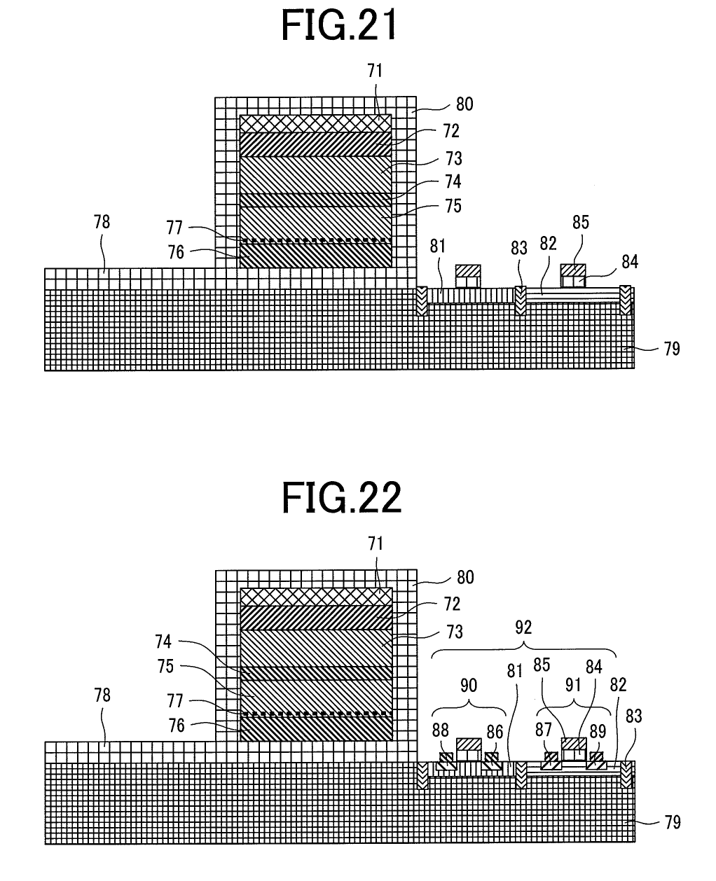

Then, a gate insulating film 84 (SiO₂) and a gate electrode 85 (polycrystalline Si) are formed by chemical vapor deposition, photolithography, and dry etching (Refer to FIG. 21).

Then, a high concentration n-type Si region 86 and a high concentration p-type Si region 87 are formed by photolithography, ion implanting, and annealing for activation. An n-type ohmic electrode 88, an a p-type ohmic electrode 89 are formed to prepare a Si CMOSFET 92 having an n-channel Si MOSFET 90 and a p-channel Si MOSFET 91 (Refer to FIG. 22).

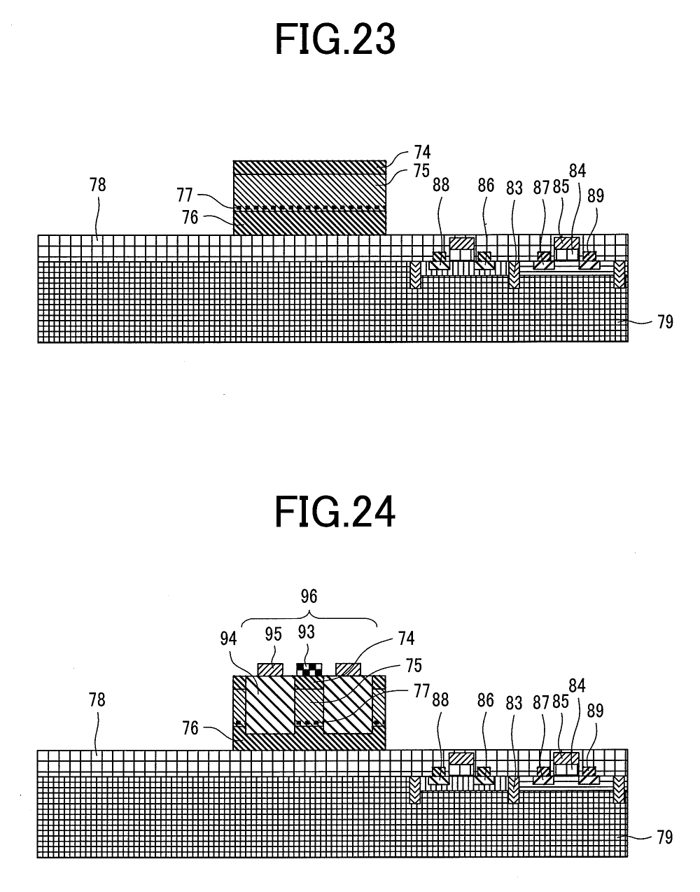

Then, the entire surface is coated with SiO₂ by chemical vapor deposition, and SiO₂ in a region for formation of an n-channel GaN FET 96 is removed by photolithography and dry etching. Then, a portion of the Si(111) substrate 71, a portion of the undoped AlGaN buffer layer 72, and a portion of the undoped GaN buffer layer 73 are removed by dry etching. Then a remaining portion of the layer 73 made of undoped GaN buffer is removed by wet etching to have the etch stop layer 74 made of undoped AlGaN exposed (FIG. 23).

Then, a refractory metal (WSi) is deposited by sputtering, and a gate electrode 93 is formed by photolithography and dry etching. Then a high concentration n-type GaN region 94 is formed using the gate electrode as a mask by Si ion implanting and annealing for activation. Then polycrystalline Si is deposited on the entire surface with the polycrystalline Si 95 left only on the high concentration n-type GaN region 94 as a buffering layer for lowering a contact resistance with the ohmic electrode (Refer to FIG. 24).

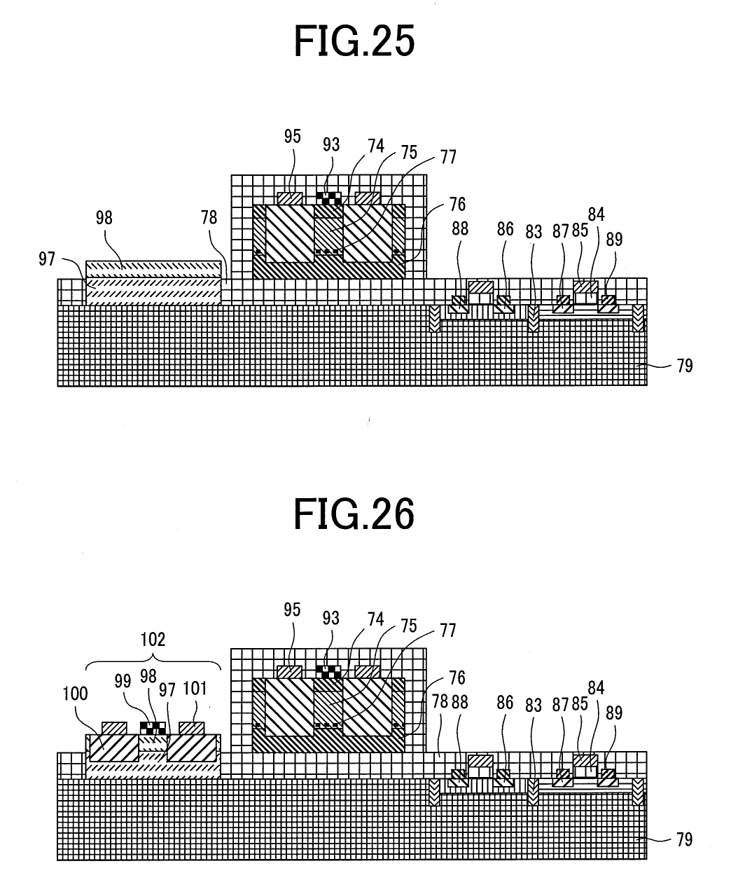

Then, SiO₂ is deposited on the entire surface by chemical vapor deposition, and the SiO₂ is removed only from the region for formation of a p-type Ge FET 102 by photolithography and dry etching. Then a buffer layer 97 made of undoped SiGe (with the thickness of 0.5 μm) and a layer 98 made of p-type Ge (with the thickness of 0.2 μm) are selectively grown by the ultra-high vacuum chemical vapor deposition (Refer to FIG. 25).

Then, a refractory metal (WSi) is deposition by sputtering, and a gate electrode 99 is formed by photolithography and dry etching. A high concentration p-type Ge/SiGe region 100 is formed by photolithography, ion implanting, and annealing for activation. Then polycrystalline Si is deposited on the entire surface, and the polycrystalline Si 101 is left only on the high concentration p-type Ge/SiGe region 100 as a buffering layer for lowering a contact resistance with the ohmic electrode (Refer to FIG. 26).

Finally, the inter-layer SiO₂ film 78 is deposited, and after a contact hole is formed by photolithography, Al is deposited on the entire surface, an Al wiring 106 is formed by photolithography and dry etching. Furthermore, a hybrid LSI comprising the Si CMOSFET 92 having the n-channel Si MOSFET 90 and 91 p-channel Si MOSFET 91 and a ultrahigh speed complementary FET having the n-channel GaN FET 96 and the p-channel Ge FET 102 is prepared (Refer to FIG. 27). Details of the structure shown in FIG. 27 are the same as those shown in other figures excluding the interlayer insulating SiO₂ film 78 and the Al wiring 106 which are newly formed, the corresponding reference numerals are omitted herefrom for simplification.

With the embodiment described above, by using polycrystalline Si on an interface between an n-type GaN having a high contact resistance and an ohmic electrode, it is possible to lower the contact resistance so as to achieve ultrahigh speed operations, and also it is possible to employ common processes for Si LSIs such as a process for forming wirings using polycrystalline Si and Al and a process for forming the wirings by dry etching without using manufacturing processes of semiconductors made of compounds such as GaN not suitable for high-density integration in semiconductor devices such as alloy electrodes, Au wiring, and formation of liftoff thereof. Therefore, even when GaN is applied to an n-channel semiconductor, it is possible to realize a high-speed LSI without dropping the integration density. Differently from semiconductors made of compounds of group-V materials such as GaAs, GaP, and GaSb having a high vapor pressure, re-evaporation of N does not occur in GaN even at a high temperature of around 1100° C., and compatibility with the Si LSI process is excellent, and the features contribute to realization of the hybrid LSIs in this embodiment. In this embodiment, a semiconductor contacting polycrystalline Si is described, and it is needless to say that the same effects as those provided in the third embodiment can be achieved by using an alloy containing GaN as a main ingredient.

Description of reference numerals in the figures are provided below.
1, 21: Substrate
2: Buffer layer
3, 23: Collector region
4, 24: Emitter region
5: Emitter contact region
6: Collector contact region
7: Surface passivation
8: Base region
9, 29: Emitter electrode
10: Emitter wiring
11: Base wiring
12, 31: Collector electrode
13: Collector wiring
30: Base electrode
51: First base layer
52: Second base layer
53: Third base layer
61: Sapphire substrate
62: n-type GaN layer
63: InGaN layer
64: p-type GaN layer
65: P-type electrode
66: n-type polycrystalline Si
67: Buffer layer
71: Si (111) substrate
72: AlGaN buffer layer
73: GaN buffer layer
74: Etch-stop layer made of AlGaN
75: GaN layer
76: AlGaN layer
77: Two-dimensional electron gas
78, 80: SiO₂
79: Si(100) substrate
81: p-type Si well
82: N-type Si well
83: SiO₂ film for separation of devices
84: Gate insulating film
85: Gate electrode
86: High concentration n-type Si region
87: High concentration p-type Si region
88: n-type ohmic electrode
89: p-type ohmic electrode
90: n-channel Si MOSFET
91: p-channel Si MOSHET
92: Si CMOSFET
93, 99: Refractory gate metal
94: High concentration n-type GaN region
95, 101: Polycrystalline Si
96: n-channel GaNFET
97: SiGe buffer layer
98: Ge layer
100: High concentration p-type Ge region
102: p-channel Ge FET
103: Ultrahigh speed complementary type FET

What is claimed is:

1. A hetero-junction bipolar transistor comprising:
a substrate
an emitter contact region;
an emitter region made of a first semiconductor material;
a base region made of a second semiconductor having a smaller energy band gap than that of the first semiconductor material;
a collector region made of the first semiconductor material; and
a collector contact region, wherein
the emitter contact region, the emitter region, the base region, the collector region, and the collector contact region are formed successively in a direction parallel to and formed above a surface of the substrate;
a buffer layer made of a third semiconductor material with an energy band gap larger than that of the first semiconductor material is provided between the emitter region, the base region, the collector region and the substrate surface; and
an emitter electrode, a base electrode, and a collector electrode are formed in contact with the emitter contact region, the base region, and the collector region, respectively.

2. The hetero-junction bipolar transistor according to claim 1, wherein the emitter region and the collector region are made of n-type InGaN, and the base region is made of p-type polycrystalline Si.

3. The hetero-junction bipolar transistor according to claim 1, wherein the emitter region and the collector region are made of n-type InGaN with the InN mole fraction in the range from 0.1 to 0.3 and the base region is made of p-type polycrystalline Si.

4. The hetero-junction bipolar transistor according to claim 1, wherein
the hetero-junction bipolar transistor is a lateral hetero-junction bipolar transistor in which the emitter region made of the first semiconductor material, the base region made of the second semiconductor having a smaller energy band gap than that of the first semiconductor material, the collector region made of the first semiconductor material are formed successively in a direction parallel to and formed above the surface of the substrate.

5. The hetero-junction bipolar transistor according to claim 1, wherein an acceptor density in the base region is higher than a donor density in the emitter region.

6. The hetero-junction bipolar transistor according to claim 2, wherein an acceptor density in the base region is higher than a donor density in the emitter region.

7. The hetero-junction bipolar transistor according to claim 1, wherein
the emitter contact region, the emitter region, the base region made of a second semiconductor having a smaller energy band gap than that of the first semiconductor material, the contact region made of the first semiconductor material, and the collector contact region are formed successively in a direction parallel to and formed above the surface of the substrate;
the buffer layer made of a third semiconductor material with an energy band gap larger than that of the first semiconductor material is provided between the emitter region, the base region, the collector region and the substrate surface;
an emitter electrode, a base electrode, and a collector electrode are formed in contact with the emitter contact region, the base region, and the collector region, respectively; and
a plurality of regions for the hetero-junction bipolar transistors are formed on a semiconductor substrate.

8. The hetero-junction bipolar transistor according to claim 2, wherein
the emitter contact region, the emitter region, the base region made of a second semiconductor having a smaller energy band gap than that of the first semiconductor material, the contact region made of the first semiconductor material, and the collector contact region are formed in a direction parallel to and formed above the surface of the substrate;
the buffer layer made of a third semiconductor material with an energy band gap larger than that of the first semiconductor material is provided between the emitter region, the base region, the collector region and the substrate surface;
an emitter electrode, a base electrode, and a collector electrode are formed in contact with the emitter contact region, the base region, and the collector region, respectively; and
a plurality of regions for the hetero-junction bipolar transistors are formed on a semiconductor substrate.

9. The hetero-junction bipolar transistor according to claim 1, wherein the emitter electrode, the base electrode, and the collector electrode are connected to each other.

10. The hetero-junction bipolar transistor according to claim 2, wherein the emitter electrode, the base electrode, and the collector electrode are connected to each other.

11. A semiconductor device comprising:
a semiconductor alloy region made of GaN or containing GaN as a main ingredient;
an ohmic electrode; and
a polycrystalline Si layer provided between the semiconductor alloy region made of GaN or containing GaN as a main ingredient and the ohmic electrode.
